(19) United States
(12) Patent Application Publication
(10) Pub. No.: US 2015/0287903 A1
(43) Pub. Date: Oct. 8, 2015

(54) PIEZOELECTRIC TRANSFORMER

(71) Applicant: Samsung Electro-Mechanics Co., Ltd., Suwon (KR)

(72) Inventors: In Wha JEONG, Suwon (KR); Hugh KIM, Suwon (KR); Jong Heum PARK, Suwon (KR); Hak Ryong KIM, Suwon (KR)

(73) Assignee: Samsung Electro-Mechanics Co., Ltd., Suwon (KR)

(21) Appl. No.: 14/606,592

(22) Filed: Jan. 27, 2015

(30) Foreign Application Priority Data
Apr. 7, 2014 (KR) 10-2014-0041198
Apr. 18, 2014 (KR) 10-2014-0046998
Jun. 25, 2014 (KR) 10-2014-0077796

(51) Int. Cl. H01L 41/107; H01L 41/083

(52) U.S. Cl. CPC H01L 41/107; H01L 41/083

(57) ABSTRACT

The piezoelectric transformer according to an exemplary embodiment includes: at least one input unit; and a plurality of output units connected to the input unit, wherein the plurality of output units output different levels of voltage.

Here, the input unit and each of the output units have an insulating layer interposed therebetween. In addition, in order to output various levels of voltage, the output units have different volumes or are formed of different materials.

### CROSS-REFERENCE TO RELATED APPLICATIONS

This application claims the priorities and benefits of Korean Patent Application Nos. 10-2014-0041198 filed on Apr. 7, 2014, 10-2014-0046998 filed on Apr. 18, 2014, and 10-2014-0077796 filed on Jun. 25, 2014, with the Korean Intellectual Property Office, the disclosures of which are incorporated herein by reference.

### BACKGROUND

The present disclosure relates to a piezoelectric transformer.

A piezoelectric transformer is an element converting electrical energy voltage levels using mechanical energy and has the following advantages, as compared to a winding-type electromagnetic transformer.

Since a piezoelectric transformer does not require coil winding, it may be miniaturized, thinned and lightened and improved productivity may be realized in terms of the mass manufacturing thereof. In addition, since a piezoelectric transformer does not generate magnetic loss through phenomena such as eddy currents or hysteresis, occurring in a winding-type transformer while being driven at high frequency, high degrees of product efficiency may be obtained. Further, since a piezoelectric transformer does not have a phase in which electrical energy is converted into magnetic energy during an energy converting process as in a case of the winding-type transformer, it may be very advantageous in terms of electromagnetic disturbance.

In addition, a winding-type transformer may have a short-circuit failure mode, causing fires or the like. However, since a piezoelectric transformer has an open failure mode, product defects may not be propagated.

### RELATED ART DOCUMENT

(Patent Document 1) Japanese Patent Laid-Open Publication No. 1997-074236

### SUMMARY

An aspect of the present disclosure may provide a small, highly efficient piezoelectric transformer using a piezoelectric ceramic.

An aspect of the present disclosure may also provide a piezoelectric transformer capable of providing various levels of output voltage.

According to an aspect of the present disclosure, a piezoelectric transformer may include: at least one input unit; and a plurality of output units connected to the input unit, wherein the plurality of output units output different levels of voltage.

The input unit and each of the output units may have each of insulating layers interposed therebetween.

In order to output various levels of voltage, the output units may have different volumes or may be formed of different materials. The insulating layers may have different shapes.

### BRIEF DESCRIPTION OF THE DRAWINGS

The above and other aspects, features and advantages of the present disclosure will be more clearly understood from the following detailed description taken in conjunction with the accompanying drawings, in which:

FIG. 1 is a perspective view schematically illustrating a piezoelectric transformer according to an exemplary embodiment in the present disclosure;

FIG. 2 is a cross-sectional view taken along line A-A of FIG. 1;

FIG. 3 is a cross-sectional view taken along line B-B of FIG. 1;

FIG. 4 is a perspective view schematically illustrating a piezoelectric transformer according to another exemplary embodiment in the present disclosure;

FIG. 5 is a cross-sectional view taken along line A-A of FIG. 4;

FIG. 6 is a cross-sectional view taken along line B-B of FIG. 4;

FIG. 7 is a perspective view schematically illustrating a piezoelectric transformer according to another exemplary embodiment in the present disclosure;

FIG. 8 is a cross-sectional view illustrating a piezoelectric transformer according to another exemplary embodiment in the present disclosure;

FIG. 9 is a cross-sectional view schematically illustrating a piezoelectric transformer according to another exemplary embodiment in the present disclosure;

FIG. 10 is a cross-sectional view schematically illustrating a piezoelectric transformer according to another exemplary embodiment in the present disclosure;

FIG. 11 is a cross-sectional view taken along line A-A of FIG. 10;

FIG. 12 is a cross-sectional view taken along line B-B of FIG. 10; and

FIGS. 13A through 13C are graphs schematically illustrating waveforms of a resonance frequency used as a piezoelectric frequency according to an exemplary embodiment in the present disclosure.

### DETAILED DESCRIPTION

Exemplary embodiments of the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements maybe exaggerated for clarity, and the same reference numerals will be used throughout to designate the same or like elements.

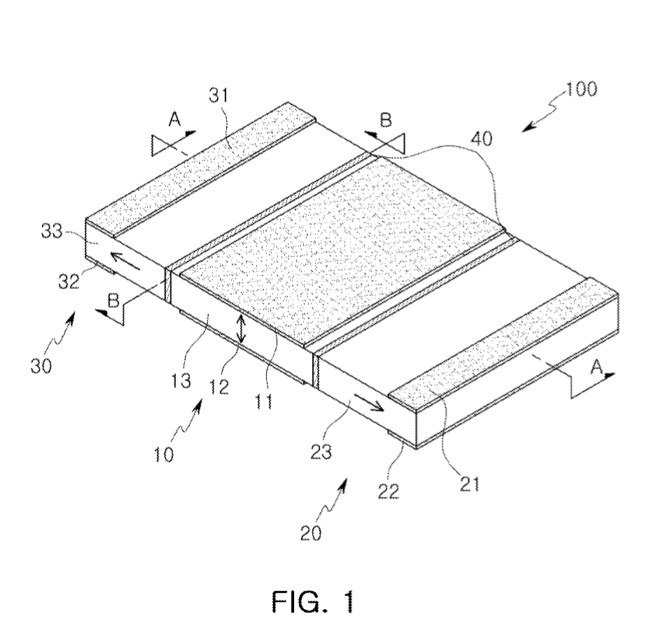

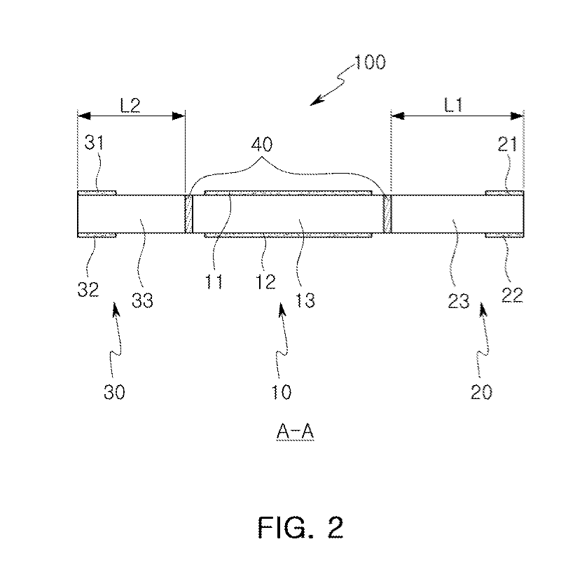

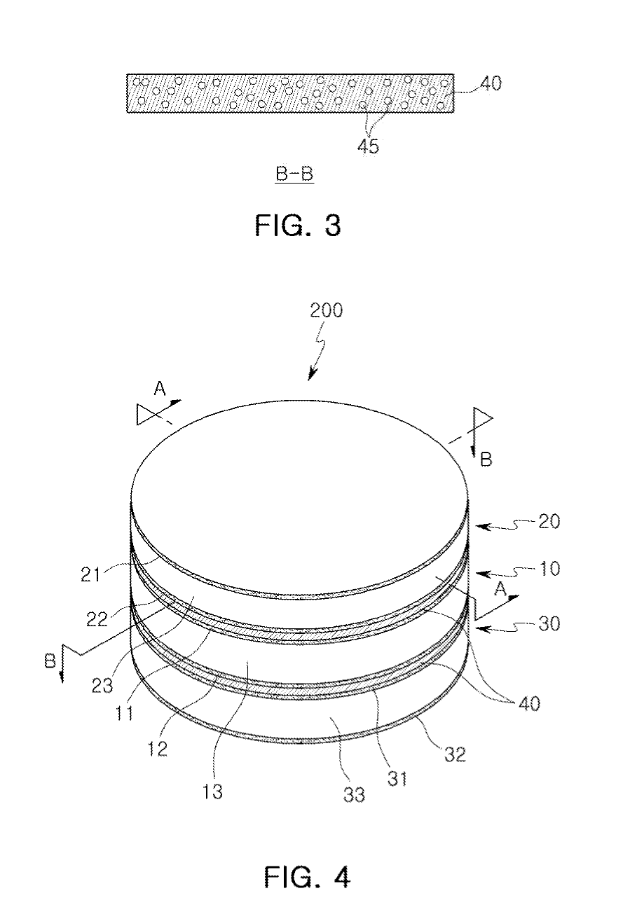

FIG. 1 is a perspective view schematically illustrating a piezoelectric transformer according to an exemplary embodiment in the present disclosure, FIG. 2 is a cross-sectional view taken along line A-A of FIG. 1, and FIG. 3 is a cross-sectional view taken along line B-B of FIG. 1. Here, FIG. 3 illustrates a cross-section of an insulating layer.

Referring to FIGS. 1 and 2, a piezoelectric transformer 100 using a piezoelectric effect according to the present exemplary embodiment may include an input unit 10, output units 20 and 30, and an insulating layer 40.

The input unit 10 may include an input piezoelectric layer 13 and input electrodes 11 and 12 formed on both surfaces of the input piezoelectric layer 13 in order to apply an input voltage.

The output units 20 and 30 may include two output piezoelectric layers 23 and 33, and output electrodes 21, 22, 31, and 32, in which the output electrodes 21 and 22 are formed on both surfaces of the output piezoelectric layer 23, and the output electrodes 31 and 32 are formed on both surfaces of the output piezoelectric layer 33.

The piezoelectric layers 13, 23, 33 used in the present exemplary embodiment may be formed of piezoelectric ceramic generally known in the art. In addition, a polarization direction of the input piezoelectric layer 13 may be formed in a thickness direction thereof and a polarization direction of the output piezoelectric layers 23 and 33 may be formed in a length direction thereof.

In the case of the piezoelectric transformer 100, when a primary voltage having a resonance frequency is applied to the input unit 10, deformation may occur in the input unit 10, and may be transferred to the output units 20 and 30 which are different regions of the same body. Then, a secondary voltage may be generated in the output units 20 and 30 due to the deformation of the output units 20 and 30.

Particularly, the output piezoelectric layers 23 and 33 according to the present exemplary embodiment may have different lengths (or widths) (L1>L2), as illustrated in FIG. 2. Since the output piezoelectric layers 23 and 33 have different lengths L1 and L2, the output piezoelectric layers 23 and 33 may generate different voltages. Therefore, the piezoelectric transformer 100 according to the present exemplary embodiment may obtain two different output voltages with respect to one input voltage.

In addition, the piezoelectric transformer 100 according to the present exemplary embodiment may have the insulating layer 40 interposed between the input unit 10 and the output units 20 and 30.

The insulating layer 40 may be formed of various materials as long as these materials have insulating properties. For example, the insulating layer 40 may be formed of a ceramic material having high insulating properties. In addition, in order to significantly reduce mechanical stress applied to the insulating layer 40, the polarization direction of the output piezoelectric layer 23 may be formed in a direction perpendicular to the insulating layer 40.

In addition, according to the present exemplary embodiment, the insulating layer 40 may be a sheet or film made of a resin material.

More specifically, the insulating layer 40 according to the present exemplary embodiment may be a thin film having insulating properties and softness may be used. In addition, as illustrated in FIG. 3, at least one hollow 45 may be formed in the insulating layer 40.

According to the present exemplary embodiment, a plurality of hollows 45 may be distributed across the entirety of the insulating layer 40. However, the present inventive concept is not limited to the above-mentioned disposition of the hollows, but various dispositions may be employed, if necessary. For example, the hollows 45 may be formed to be concentrated on any one side or to be clustered at several points, or only a single hollow 45 having a large size may be formed.

The hollow 45 may be filled with air or may be formed as an empty space in a vacuum state. Therefore, the hollow 45 may block the connections between the input unit 10 and the output units 20 and 30.

An input side (e.g., a primary side) of the piezoelectric transformer 100 according to the present exemplary embodiment may be completely separated from an output side (e.g., a secondary side) thereof by the insulating layer 40. That is, a ground of the input side and a ground of the output side may not be electrically connected to each other, and consequently, the input unit 10 and the output units 20 and 30 may each configure an independent circuit.

In addition, the piezoelectric transformer 100 according to the present exemplary embodiment may facilitate the transfer of vibrations of the input unit 10 to the output units 20 and 30 via the insulating layer 40 having softness.

In a case in which the insulating layer 40 is formed of a ceramic material, the degree of fatigue due to the vibrations may be increased, and thus, cracks may occur in the insulating layer 40 or the insulating layer 40 may be damaged. In addition, the vibrations of the input unit 10 may not be smoothly transferred to the output units 20 and 30 due to hardness of the ceramic material.

Therefore, in order to increase vibration transfer efficiency, the piezoelectric transformer 100 according to the present exemplary embodiment may include the insulating layer 40 formed of a thin film having softness.

As the insulating layer 40 has softness, the piezoelectric transformer 100 according to the present exemplary embodiment may prevent crack occurrence in the insulating layer 40 or damage to the insulating layer 40, a lifespan of the piezoelectric transformer 100 may be increased.

In addition, the piezoelectric transformer 100 according to the present exemplary embodiment may significantly increase the vibrations transferred from the input unit 10, by the hollows 45 formed in the insulating layer 40.

More specifically, as the insulating layer 40 according to the present exemplary embodiment has the hollows 45 formed therein, a volume of the insulating layer 40 may be substantially reduced as compared to that of an insulating layer having no hollows, and the input unit 10 and the output units 20 and 30 may be connected through a minimum area. Therefore, during the transfer of the vibrations of the input unit 10 to the insulating layer 40, the vibrations may be efficiently transferred to the output units 20 and 30 while an attenuation of the vibrations is significantly reduced.

Consequently, a vibration frequency applied to the input unit 10 may be increased. In addition, since a driving frequency of the piezoelectric transformer 100 may be dramatically increased, the present inventive concept may be easily applied to a high frequency transformer.

The piezoelectric transformer 100 according to the present exemplary embodiment having the above-mentioned configurations alone may provide desired levels of voltage to an electronic apparatus, a substrate, or the like requiring various voltage levels, whereby an electronic device may be miniaturized and a manufacturing time of the electronic device may also be reduced.

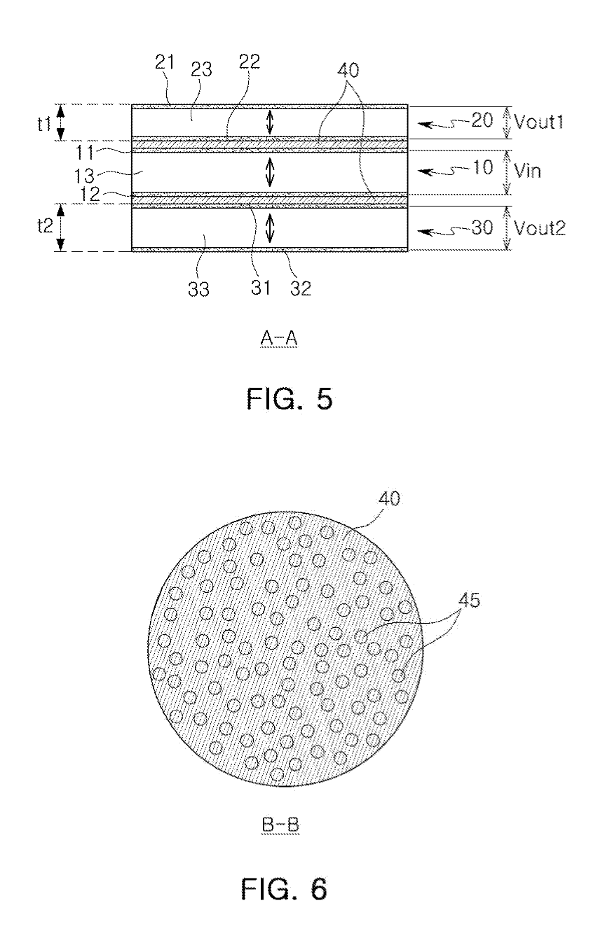

FIG. 4 is a perspective view schematically illustrating a piezoelectric transformer according to another exemplary embodiment in the present disclosure, FIG. 5 is a cross-sectional view taken along line A-A of FIG. 4, and FIG. 6 is a cross-sectional view taken along line B-B of FIG. 4. Here, FIG. 6 illustrates a cross-section of an insulating layer.

Referring to FIGS. 4 and 5, a piezoelectric transformer 200 according to the present exemplary embodiment may be a stacked-type piezoelectric transformer and may include an input unit 10, output units 20 and 30, and an insulating layer 40, similar to the previous exemplary embodiment.

The input unit 10 may include an input piezoelectric layer 13 and input electrodes 11 and 12 formed on the top and bottom of the input piezoelectric layer 13 in order to apply an input voltage.

In addition, the output units 20 and 30 may be formed on top and bottom surfaces of the input unit 10, respectively, and may include output piezoelectric layers 23 and 33, and output electrodes 21, 22, 31, and 32 for outputting output voltages, in which the output electrodes 21 and 22 are formed on top and bottom surfaces of the output piezoelectric layer 23, and the output electrodes 31 and 32 are formed on top and bottom surfaces of the output piezoelectric layer 33.

According to the present exemplary embodiment, the input unit 10 and the output units 20 and 30 may be formed in a disc shape, and the overall shape of the stacked-type piezoelectric transformer 200 is cylindrical byway of example.

However, the shape of the transformer is not limited thereto, but may be varied, if necessary. For example, the input unit 10 and the output units 20 and 30 may be formed to have a polyprism shape or an elliptic cylindrical shape.

In addition, the insulating layer 40 may be formed between the input unit 10 and the output units 20 and 30. The insulating layer 40 in the present exemplary embodiment may be a thin film having softness. Alternatively, the insulating layer 40 may be formed of a ceramic material having high insulating properties, similar to the previous exemplary embodiment. In addition, the insulating layer 40 may have at least one hollow 45 formed therein, as illustrated in FIG. 6.

The piezoelectric transformer 200 according to the present exemplary embodiment may have two output units 20 and 30, and one input unit 10 interposed between the two output units 20 and 30.

In addition, as illustrated in FIG. 5, a thickness t1 of the first output unit 20 and a thickness t2 of the second output unit 30 may be different from each other, and layers forming inner portions of the first and second output units 20 and 30 may also be different from each other. The first output unit 20 and the second output unit 30 may output different voltages Vₒᵤₜ1 and Vₒᵤₜ2 with respect to one input voltage Vᵢₙ.

In addition, polarization directions of the first output unit 20 and the second output unit 30 may be formed in the same direction or in different directions.

In addition, the first output unit 20 and the second output unit 30 in the present exemplary embodiment are formed in the disc shape having the same diameter by way of example, but various modifications to the first output unit 20 and the second output unit 30 may be made, if necessary. For example, the first output unit 20 and the second output unit 30 may have different sizes, thicknesses, shapes, or the like.

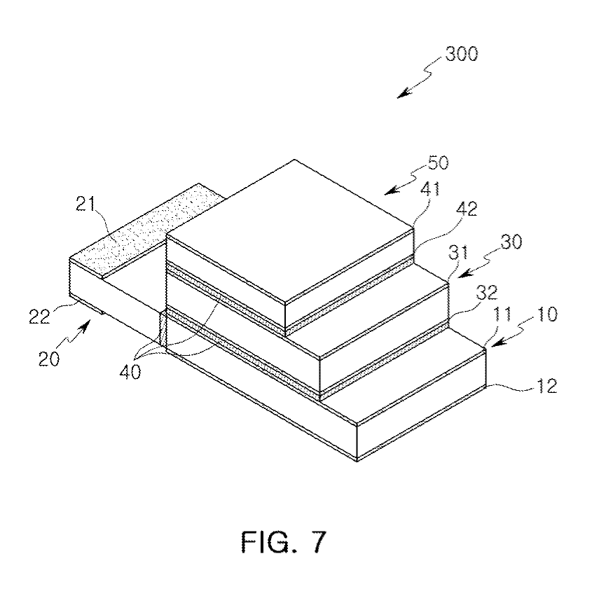

FIG. 7 is a perspective view schematically illustrating a piezoelectric transformer according to another exemplary embodiment in the present disclosure.

Referring to FIG. 7, a piezoelectric transformer 300 according to the present exemplary embodiment may have one input unit 10 and a plurality of output units 20, 30, and 50 having different sizes and coupled to the input unit 10.

A polarization direction of the input unit 10 may be formed in a thickness direction thereof.

A first output unit 20 may be coupled to a side surface of the input unit 10, similar to the exemplary embodiment of FIG. 1, and a polarization direction thereof may be formed in a length direction thereof. In addition, a second output unit 30 may be stacked on the top of the input unit 10, similar to the exemplary embodiment of FIG. 4, and a polarization direction thereof may be formed in a thickness direction thereof.

In addition, a third output unit 50 may be stacked on the top of the second output unit 30 and a polarization direction thereof may be formed in a thickness direction thereof. Therefore, the third output unit 50 may be vibrated according to vibrations of the second output unit 30 and may output an output voltage.

Here, the insulating layer 40 maybe interposed between each of output units 20, 30, and 50 and the input unit 10. In addition, each insulating layer 40 may have at least one hollow formed therein, as in the previous exemplary embodiments.

Meanwhile, in the piezoelectric transformer 300 according to the present exemplary embodiment, contact areas between the plurality of output units 20, 30 and 50 and the input unit 10 may be different from each other. The magnitude of the vibrations transferred may also differ, and thus, the respective output units 20, 30 and 50 may output different voltages.

In addition, the configuration of the piezoelectric transformer may be varied in order to provide various levels of output voltage with respect to one input voltage.

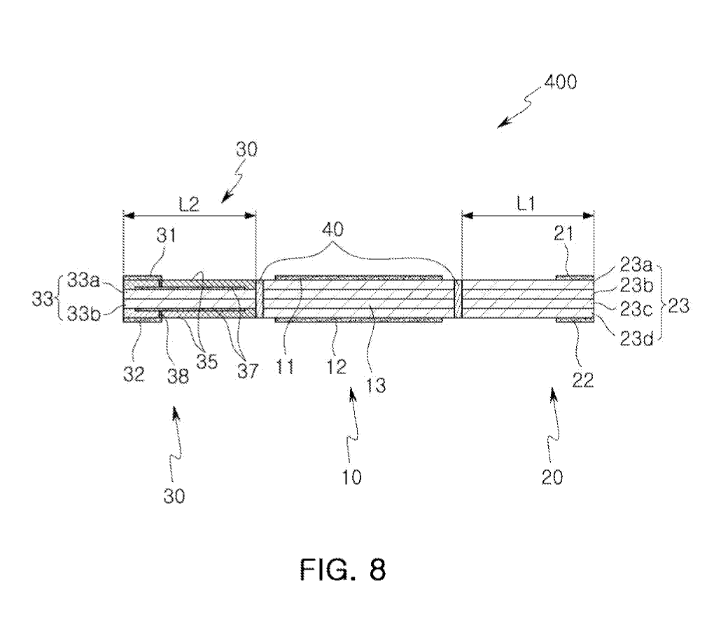

FIG. 8 is a cross-sectional view illustrating a piezoelectric transformer according to another exemplary embodiment in the present disclosure.

Referring to FIG. 8, a piezoelectric transformer 400 according to the present exemplary embodiment may include two output units 20 and 30 having the same size (or volume).

Therefore, the output units 20 and 30 may have the same lengths (or widths) L1 and L2, but components forming inner portions of the output units 20 and 30 may differ.

A first output unit 20 may include an output piezoelectric layer 23 which is formed by stacking four ceramic layers 23a to 23d. In addition, an input piezoelectric layer 13 may also be formed by stacking four ceramic layers. On the other hand, a second output unit 30 may include an output piezoelectric layer 33 which is formed by stacking two ceramic layers 33a and 33b.

Here, the ceramic layers 23a to 23d, 33a and 33b may be divided by a ceramic green sheet used at the time of manufacturing the piezoelectric layers 23 and 33, and may be formed of the same material.

In addition, in order to match the overall shape (or volume) of the second output unit 30 to that of the first output unit 20, an insulating layer 35 may be added to the output piezoelectric layer 33 of the second output unit 30.

According to the present exemplary embodiment, the insulating layer 35 may be disposed on the top and bottom of the output piezoelectric layer 33 of the second output unit 30, and may be formed to have the same thickness as that of the ceramic layers 23a and 23d of the first output unit 20.

Thus, the second output unit 30 may have a total of four layers by including two insulating layers 35, and may be formed to have the same size (or volume) as that of the first output unit 20.

The insulating layer 35 may be formed of an insulating material. For example, the insulating layer 35 may be formed of an insulating ceramic material.

In addition, in order to extract a voltage from the output piezoelectric layer 33 which is disposed between the insulating layers 35, internal electrodes 37 may be formed on one surface or both surfaces of the output piezoelectric layer 33. In addition, the internal electrodes 37 may be electrically connected to output electrodes 31 and 32 disposed outside the insulating layers 35 through conductive vias 38, or the like.

The piezoelectric transformer 400 according to the present exemplary embodiment having the above-mentioned configuration may output different levels of voltage by differing the stacked number of layers, that is, the ceramic layers 23a to 23d and the ceramic layers 33a and 33b in the output piezoelectric layers 23 and 33 of the first output unit 20 and the second output unit 30.

Meanwhile, in the present exemplary embodiment, the four ceramic layers are stacked in the first output unit 20 and the input unit 10 and the two ceramic layers are stacked in the second output unit 30 by way of example, but the configuration of the input and output units is not limited thereto. For example, the stacked number of ceramic layers in the second output unit 30, the first output unit 20, and the input unit 10 may be different from each other.

In addition, one surface (the top surface or the bottom surface) of the second output unit 30 may be exposed to the outside without disposing the ceramic layers 33a and 33b of the second output unit 30 between the insulating layers 35, or only the ceramic layers 33a and 33b may be formed by omitting the insulating layers 35.

Alternatively, the second output unit 30 may be formed by forming the insulating layers 35 using a ceramic material and alternately stacking the insulating layers 35 and the ceramic layers 33a and 33b.

More specifically, the second output unit 30 may be formed by stacking the ceramic layer 33a on one insulating layer 35 and sequentially stacking the insulating layer 35 and the ceramic layer 33b thereon.

In this case, at least one internal electrode may be interposed between the insulating layers 35 and the ceramic layers 33a and 33b, if necessary, and at least two internal electrodes may be connected to each other.

Meanwhile, the ceramic layers 33a and 33b and the insulating layers 35 in the previous exemplary embodiment are formed to have the same thickness by way of example, but are not limited thereto. For example, the thicknesses of the ceramic layers 33a and 33b may be different from the thicknesses of the insulating layers 35. In addition, the ceramic layers 33a and 33b may be formed to have different thicknesses.

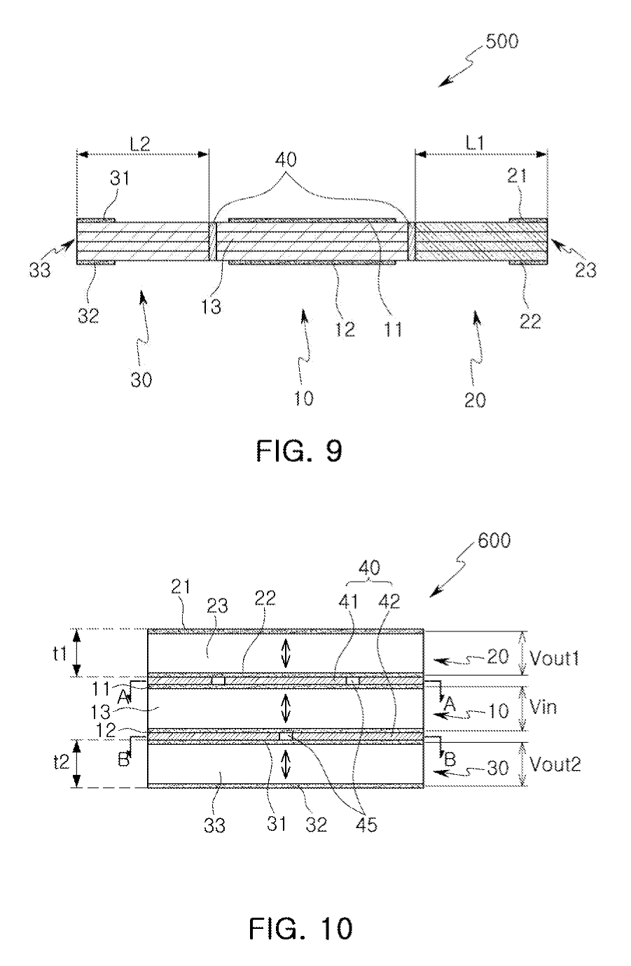

FIG. 9 is a cross-sectional view schematically illustrating a piezoelectric transformer according to another exemplary embodiment in the present disclosure.

Referring to FIG. 9, a piezoelectric transformer 500 according to the present exemplary embodiment may also include two output units 20 and 30 having the same size (or volume), and materials forming inner portions of the output units 20 and 30 may differ.

The piezoelectric transformer 500 according to the present exemplary embodiment may have an output piezoelectric layer 33 of a second output unit 30 and an output piezoelectric layer 23 of a first output unit 20 which are formed of different materials.

For example, the output piezoelectric layer 23 of the first output unit 20 may be formed by sintering a soft piezoelectric ceramic material, while the output piezoelectric layer 33 of the second output unit 30 may be formed by sintering a hard piezoelectric ceramic material. In addition, the output piezoelectric layer 23 of the first output unit 20 and the output piezoelectric layer 33 of the second output unit 30 may be formed by combining the soft piezoelectric ceramic material and the hard piezoelectric ceramic material with different combination ratios, if necessary.

In addition, the materials of the first and second output units are not limited thereto, and may be varied, if necessary. For example, the output piezoelectric layer 33 of the second output unit 30 may be formed by sintering barium titanate (BaTiO₃) and the output piezoelectric layer 23 of the first output unit 20 may be formed of lead zirconate titanate (PZT).

Even when the second output unit 30 and the first output unit 20 are formed to have the same volume, the levels of output voltage may be different from each other due to a difference in the materials. Therefore, various levels of voltage may be provided by a single piezoelectric transformer 500.

Meanwhile, according to the present exemplary embodiment, an input piezoelectric layer 13 may be formed of the same material as that of any one of the first output unit 20 and the second output unit 30. However, the material of the input piezoelectric layer 13 is not limited thereto, but may be varied. For example, the input piezoelectric layer 13 may be formed of a material different from that of the first and second output units 20 and 30.

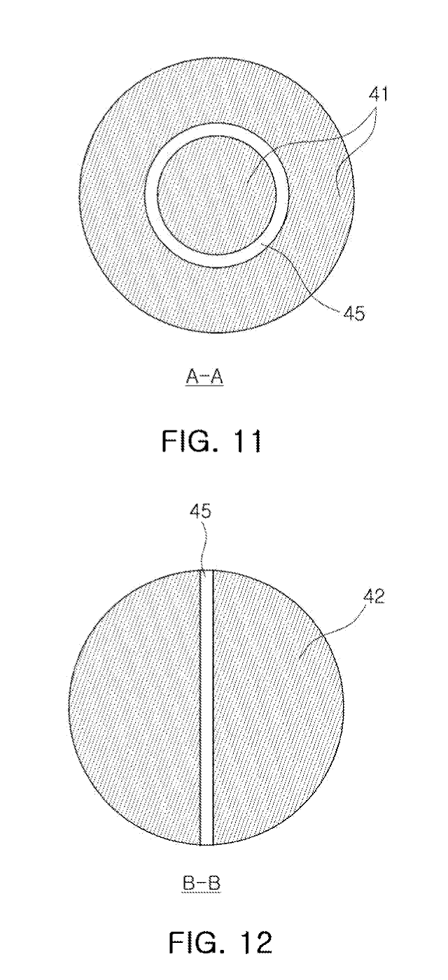

FIG. 10 is a cross-sectional view schematically illustrating a piezoelectric transformer according to another exemplary embodiment in the present disclosure, FIG. 11 is a cross-sectional view taken along line A-A of FIG. 10, and FIG. 12 is a cross-sectional view taken along line B-B of FIG. 10.

First, referring to FIG. 10, the shape of a piezoelectric transformer 600 according to the present exemplary embodiment maybe similar to that of the piezoelectric transformer according to the exemplary embodiment of FIG. 4, but is not limited thereto.

An input unit 10 of the piezoelectric transformer 600 according to the present exemplary embodiment may include an input piezoelectric layer 13 and input electrodes 11 and 12 formed on the top and bottom of the input piezoelectric layer 13 in order to apply an input voltage.

Output units 20 and 30 may be formed on top and bottom surfaces of the input unit 10, respectively, and may include output electrodes 21, 22, 31, and 32 for outputting output voltages, in which the output electrodes 21 and 22 are formed on top and bottom surfaces of the output piezoelectric layer 23, and the output electrodes 31 and 32 are formed on top and bottom surfaces of the output piezoelectric layer 33.

In addition, the output units 20 and 30 according to the present exemplary embodiment may have the same size and may be formed of the same material. Therefore, a thickness t1 of a first output unit 20 may be the same as a thickness t2 of a second output unit 30.

An insulating layer 40 may be formed between the input unit 10 and the output units 20 and 30.

The insulating layer 40 according to the present exemplary embodiment may be formed of a ceramic material having high insulating properties or may be a thin film having softness, similar to the previous exemplary embodiments.

In addition, the insulating layer 40 according to the present exemplary embodiment may include a first insulating layer 41 formed between the input unit 10 and the first output unit 20 and a second insulating layer 42 formed between the input unit 10 and the second output unit 30, and the first insulating layer 41 and the second insulating layer 42 may be formed to be different from each other.

For example, the first insulating layer 41 and the second insulating layer 42 maybe formed of different materials. In addition, the first insulating layer 41 and the second insulating layer 42 may be formed to have different sizes, volumes, or shapes.

More specifically, the first insulating layer 41 and the second insulating layer 42 may have at least one groove 45 (or at least one hollow) formed therein, as illustrated in FIGS. 11 and 12. In addition, the groove 45 formed in the first insulating layer 41 and the groove 45 formed in the second insulating layer 42 may be formed in different shapes.

As the grooves 45 formed in the respective insulating layers 41 and 42 are formed to have different shapes, the first insulating layer 41 and the second insulating layer 42 may also have different volumes. Consequently, magnitude of vibrations transferred to the first output unit 20 through the first insulating layer 41 may be different from magnitude of vibrations transferred to the second output unit 30 through the second insulating layer 42.

Therefore, even when the first output unit 20 and the second output unit 30 are formed to have the same size and are formed of the same material, the magnitudes of vibrations may differ, resulting in different levels of output voltage.

The piezoelectric transformer according to the present exemplary embodiment may have different levels of voltage output from the output units due to the shapes of the insulating layers, regardless of the sizes and shapes of the first output unit and the second output unit.

Therefore, the first output unit and the second output unit may be manufactured to have the same configuration through the same process, and thus, the piezoelectric transformer may be easily manufactured.

Meanwhile, the first insulating layer and the second insulating layer in the present exemplary embodiment are formed to be different from each other using the different groove shapes by way of example. However, the first and second insulating layers are not limited thereto and may be formed in various manners.

For example, the first insulating layer and the second insulating layer may be formed to have different thicknesses or may be formed to have different hardness or softness. For example, the grooves formed in the first insulating layer and the second insulating layer may be formed to have different widths, or may be filled with different materials.

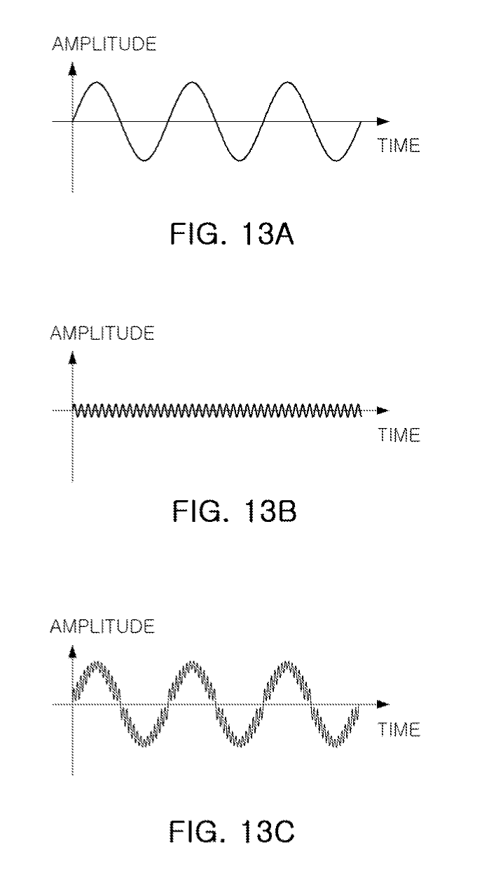

FIGS. 13A through 13C are graphs schematically illustrating waveforms of a resonance frequency used as a piezoelectric frequency according to an exemplary embodiment in the present disclosure.

In general, a piezoelectric ceramic (e.g., piezoelectric layer) may have several resonance frequencies. Here, the lowest resonance frequency is referred to as a primary vibration mode, and resonance frequencies higher than the lowest resonance frequency are sequentially referred to as a secondary vibration mode, a tertiary vibration mode, and so on.

The piezoelectric transformer (e.g., 400 of FIG. 8) according to the above-described exemplary embodiments may generate vibrations by setting any one resonance frequency of several resonance frequencies as a basic resonance frequency (hereinafter, a first resonance frequency (see FIG. 13A) and applying a voltage corresponding to the basic resonance frequency to the input unit 10.

Here, the first resonance frequency may be defined as a resonance frequency capable of obtaining the highest vibration efficiency for the entire piezoelectric transformer (e.g., all of the input unit and the output units), the input unit 10, or the output units 20 and 30.

In addition, the piezoelectric transformer according to the present exemplary embodiment may apply the voltage to the input unit 10 at an input frequency (see FIG. 13C) corresponding to a combination of a second resonance frequency (see FIG. 13B) and the first resonance frequency.

The second resonance frequency may be different from the first resonance frequency and may be defined as any one of several resonance frequencies of a specific output unit (e.g., the first output unit).

Since the piezoelectric transformers according to exemplary embodiments of the present disclosure have the output units 20 and 30 which are formed to have different sizes, volumes, materials, or the like in order to output different voltages, the output units 20 and 30 may have different resonance frequencies.

Therefore, in a case in which the voltage is applied to the input unit 10 at the second resonance frequency, only a specific output unit (e.g., the first output unit) corresponding to the second resonance frequency may be affected by the second resonance frequency and the other output unit (e.g., the second output unit) may not be affected thereby.

Since the specific output unit (e.g., the first output unit) is affected by both the first resonance frequency and the second resonance frequency, the vibration efficiency may be increased.

Meanwhile, FIG. 13 describes a case in which the second resonance frequency is set to be higher than the first resonance frequency by way of example, but the resonance frequencies are not limited thereto. For example, the second resonance frequency may also be set to be lower than the first resonance frequency. In addition, if necessary, third and fourth resonance frequencies may be additionally used.

The above-described exemplary embodiments may be modified in various manners.

For example, in the exemplary embodiment of FIG. 7, the input unit is disposed at the bottom of the transformer, but the position thereof is not limited thereto. For example, the input unit may be disposed in a position in which the second output unit is formed.

As set forth above, according to exemplary embodiments of the present disclosure, a piezoelectric transformer alone may provide desired levels of voltage to an electronic apparatus, a substrate, or the like requiring various levels of voltage, whereby an electronic device may be miniaturized and a manufacturing time of the electronic device may be reduced.

While exemplary embodiments have been shown and described above, it will be apparent to those skilled in the art that modifications and variations could be made without departing from the scope of the present invention as defined by the appended claims.

What is claimed is:

1. A piezoelectric transformer, comprising:
at least one input unit; and
a plurality of output units connected to the input unit,
wherein the plurality of output units output different levels of voltage.

2. The piezoelectric transformer of claim 1, further comprising an insulating layer interposed between the input unit and each of the output units.

3. The piezoelectric transformer of claim 1, wherein the insulating layer is formed of a ceramic material or a thin insulating film.

4. The piezoelectric transformer of claim 1, wherein the insulating layer has at least one hollow.

5. The piezoelectric transformer of claim 2, wherein the plurality of output units include a first output unit extended from one surface of the input unit and a second output unit extended from the other surface of the input unit, and
the insulating layer includes a first insulating layer disposed between the input unit and the first output unit and a second insulating layer disposed between the input unit and the second output unit.

6. The piezoelectric transformer of claim 5, wherein the first and second insulating layers are formed of different materials.

7. The piezoelectric transformer of claim 5, wherein the first and second insulating layers have different volumes.

8. The piezoelectric transformer of claim 5, wherein each of the first and second insulating layers has at least one groove, and
the groove provided in the first insulating layer and the groove provided in the second insulating layer have different shapes.

9. The piezoelectric transformer of claim 5, wherein the first and second output units include respective piezoelectric layers in which ceramic layers are stacked, and
the piezoelectric layer of the first output unit and the piezoelectric layer of the second output unit include different amounts of ceramic layers.

10. The piezoelectric transformer of claim 9, wherein the piezoelectric layer of the first output unit is formed of a soft piezoelectric ceramic material, and
the piezoelectric layer of the second output unit is formed of a hard piezoelectric ceramic material.

11. The piezoelectric transformer of claim 5, wherein the first and second output units have the same first resonance frequency which is a basic resonance frequency, and different second resonance frequencies.

12. The piezoelectric transformer of claim 1, wherein the plurality of output units have different volumes.

13. The piezoelectric transformer of claim 1, wherein the plurality of output units are formed of different materials.

14. The piezoelectric transformer of claim 1, wherein the plurality of output units are stacked on one surface of the input unit.

15. The piezoelectric transformer of claim 1, wherein at least two of the plurality of output units have different areas in contact with the input unit.

16. A piezoelectric transformer, comprising:
at least one input unit;
a plurality of output units connected to the input unit; and
a plurality of insulating layers disposed between the input unit and each of the plurality of output units and having different shapes.

17. The piezoelectric transformer of claim 16, wherein the plurality of output units have the same shape and the same size.

18. The piezoelectric transformer of claim 16, wherein the plurality of insulating layers have grooves, and have different shapes depending on shapes of the grooves.
